(19) United States
(12) Patent Application Publication
(10) Pub. No.: US 2026/0026030 A1
(43) Pub. Date: Jan. 22, 2026

(54) SEMICONDUCTOR DEVICES

(71) Applicant: Samsung Electronics Co., Ltd., Suwon-si (KR)

(72) Inventors: Changwoo NOH, Suwon-si (KR); Beomjin PARK, Suwon-si (KR); Seunggeun JUNG, Suwon-si (KR); Younggun KO, Suwon-si (KR); Dongwon KIM, Suwon-si (KR)

(73) Assignee: Samsung Electronics Co., Ltd., Suwon-si (KR)

(21) Appl. No.: 19/003,563

(22) Filed: Dec. 27, 2024

(30) Foreign Application Priority Data
Jul. 17, 2024 (KR) 10-2024-0094582

(51) Int. Cl. H10D 30/00; H10D 30/01

(52) U.S. Cl. CPC H10D 30/502; H10D 30/0191; H10D 30/0198

(57) ABSTRACT

A semiconductor device includes a substrate insulating layer, a gate structure extending in a first direction on the substrate insulating layer, a plurality of channel layers spaced apart from each other in a second direction, the second direction perpendicular to an upper surface of the substrate insulating layer, the plurality of channel layers on the substrate insulating layer and surrounded by the gate structure, a first source/drain region and a second source/drain region, on both sides of the gate structure and connecting to the plurality of channel layers, a first spacer layer below the first source/drain region, and a second spacer layer below the second source/drain region, and a backside contact plug partially recessing a lower surface of the first source/drain region through the substrate insulating layer and the first spacer layer.

### CROSS-REFERENCE TO RELATED APPLICATION(S)

This application claims benefit of priority to Korean Patent Application No. 10-2024-0094582 filed on Jul. 17, 2024 in the Korean Intellectual Property Office, the disclosure of which is incorporated herein by reference in its entirety.

### BACKGROUND

Some example embodiments of the inventive concepts relate to a semiconductor device.

As demand for higher performance, higher speed, and/or multifunctionality of semiconductor devices increases, degrees of integration of semiconductor devices may also be increasing. In accordance with the trend toward a higher degree of integration of semiconductor devices, semiconductor devices having a backside power delivery network (BSPDN) structure in which power rails are disposed on a backside of a wafer are being developed. In addition, efforts are being made to develop semiconductor devices including FinFET devices having a three-dimensional channel structure in order to overcome limitations of operating characteristics due to reductions in size of a planar metal oxide semiconductors FET (MOSFET) devices.

### SUMMARY

Some example embodiments the inventive concepts are to provide a semiconductor devices having improved reliability.

According to some example embodiments of the inventive concepts, a semiconductor device includes a substrate insulating layer, a gate structure extending in a first direction on the substrate insulating layer, a plurality of channel layers spaced apart from each other in a second direction, the second direction perpendicular to an upper surface of the substrate insulating layer, the plurality of channel layers on the substrate insulating layer and surrounded by the gate structure, a first source/drain region and a second source/drain region, on both sides of the gate structure and connecting to the plurality of channel layers, a first spacer layer below the first source/drain region, and a second spacer layer below the second source/drain region, and a backside contact plug partially recessing a lower surface of the first source/drain region through the substrate insulating layer and the first spacer layer. Each of the first and second source/drain regions includes a first epitaxial layer covering side surfaces of the plurality of channel layers, and a second epitaxial layer on the first epitaxial layer, the first source/drain region includes a backside epitaxial layer covering an upper portion of the backside contact plug, and a concentration of a non-silicon element included in the backside epitaxial layer is greater than a concentration of a non-silicon element included in the second epitaxial layer.

According to some example embodiments of the inventive concepts, a semiconductor device includes a gate structure extending in one direction, a source/drain region on a side of the gate structure, a backside contact plug connecting to the source/drain region from below the source/drain region, and a spacer layer surrounding at least a portion of the backside contact plug below the source/drain region. The source/drain region includes a first epitaxial layer contacting the gate structure, a second epitaxial layer on the first epitaxial layer, and a backside epitaxial layer between the second epitaxial layer and the backside contact plug. The first epitaxial layer includes a non-silicon element having a first concentration, the second epitaxial layer includes a non-silicon element having a second concentration, the second concentration greater than the first concentration, and the backside epitaxial layer includes a non-silicon element having a third concentration, the third concentration greater than the second concentration.

According to some example embodiments of the inventive concepts, a semiconductor device includes a substrate insulating layer, a gate structure extending in a first direction on the substrate insulating layer, a plurality of channel layers spaced apart from each other in a second direction, the second direction perpendicular to an upper surface of the substrate insulating layer, the plurality of channel layers on the substrate insulating layer, and surrounded by the gate structure, a first source/drain region on a first side of the gate structure and connecting to the plurality of channel layers, a second source/drain region on a second side of the gate structure, the second side opposite to the first side and connecting to the plurality of channel layers, a first spacer layer between the first source/drain region and the substrate insulating layer, a second spacer layer between the second source/drain region and the substrate insulating layer, a backside contact plug penetrating the substrate insulating layer and the first spacer layer and connecting to the first source/drain region, and a front side contact plug partially recessing the upper surface of the second source/drain region. The first source/drain region includes a backside epitaxial layer contacting the backside contact plug, and a concentration of a non-silicon element included in the backside epitaxial layer is greater than a concentration of a non-silicon element included in the second source/drain region.

### BRIEF DESCRIPTION OF DRAWINGS

The above and other aspects, features, and advantages of the inventive concepts will be more clearly understood from the following detailed description, taken in conjunction with the accompanying drawings, in which:

FIG. 1 is a schematic plan view illustrating a semiconductor device according to some example embodiments.

FIGS. 2A and 2B are schematic cross-sectional views illustrating a semiconductor device according to some example embodiments.

FIG. 2C is a schematic enlarged view illustrating a semiconductor device according to some example embodiments.

FIG. 3A is a schematic cross-sectional view illustrating a semiconductor device according to some example embodiments.

FIG. 3B is a schematic enlarged view illustrating a semiconductor device according to some example embodiments.

FIG. 4A is a schematic cross-sectional view illustrating a semiconductor device according to some example embodiments.

FIG. 4B is a schematic enlarged view illustrating a semiconductor device according to some example embodiments.

FIG. 5 is a schematic cross-sectional view illustrating a semiconductor device according to some example embodiments.

FIG. 6 is a schematic cross-sectional view illustrating a semiconductor device according to some example embodiments.

FIG. 7 is a schematic cross-sectional view illustrating a semiconductor device according to some example embodiments.

FIGS. 8 to 21 are views illustrating a process sequence illustrating a method of manufacturing a semiconductor device according to some example embodiments.

FIGS. 22 to 24 are views illustrating a process sequence illustrating a method of manufacturing a semiconductor device according to some example embodiments.

### DETAILED DESCRIPTION

Hereinafter, some example embodiments will be described with reference to the attached drawings. Hereinafter, terms such as ‘on,’ ‘upper,’ ‘upper portion,’ ‘upper surface,’ ‘below,’ ‘lower,’ ‘lower portion,’ ‘lower surface,’ ‘side surface,’ and the like can be understood to refer to the drawings, except when they are indicated separately by drawing symbols.

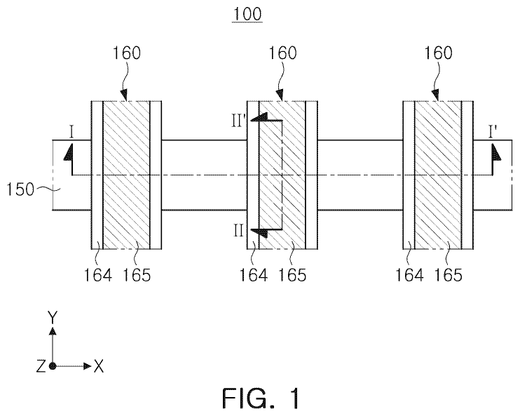

FIG. 1 is a schematic plan view illustrating a semiconductor device according to some example embodiments. For convenience of explanation, only some components of the semiconductor device may be illustrated in FIG. 1.

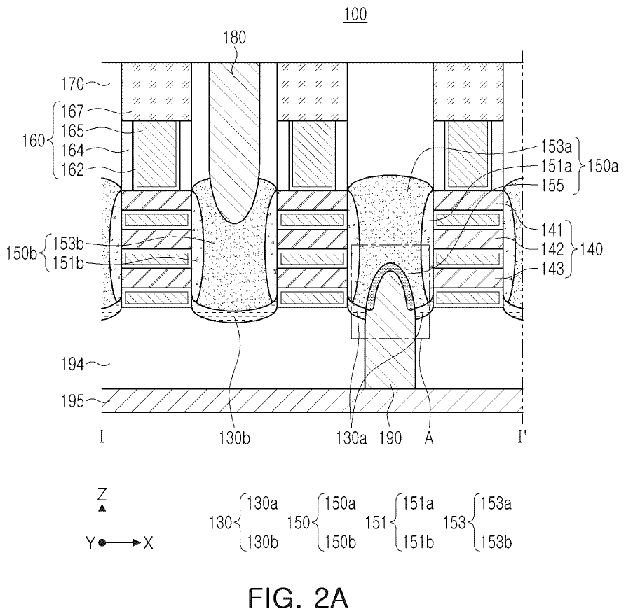

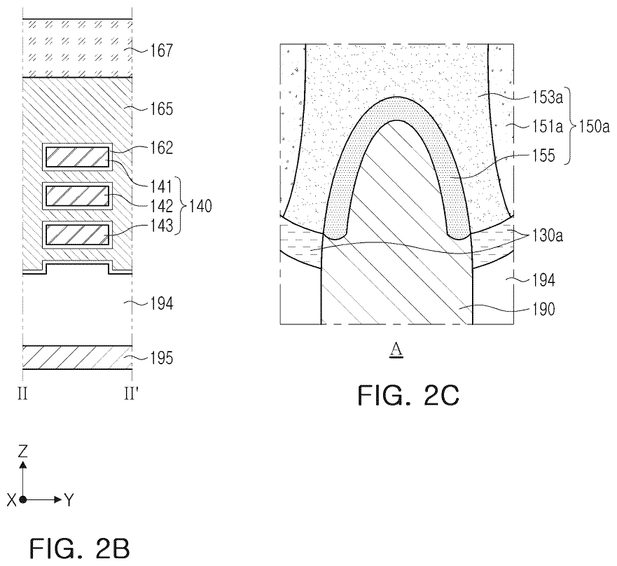

FIGS. 2A and 2B are schematic cross-sectional views illustrating a semiconductor device according to some example embodiments. FIG. 2A illustrates a cross-section of the semiconductor device of FIG. 1, taken along line I-I′. FIG. 2B illustrates a cross-section of the semiconductor device of FIG. 1, taken along line II-II′.

FIG. 2C is a schematic enlarged view illustrating a semiconductor device according to some example embodiments. FIG. 2C is an enlarged view illustrating a portion ‘A’ of FIG. 2A.

Referring to FIGS. 1 to 2C, a semiconductor device 100 may include a substrate insulating layer 194, gate structures 160 extending in one direction on the substrate insulating layer 194 and each including a gate electrode 165, channel structures 140 including first to third channel layers 141, 142, and 143 disposed vertically spaced apart from each other on the substrate insulating layer 194, source/drain regions 150 contacting the channel structures 140, spacer layers 130 disposed below the source/drain regions 150, a backside contact plug 190 penetrating the substrate insulating layer 194 and a first spacer layer 130a and connected to a first source/drain region 150a, a front side contact plug 180 penetrating an interlayer insulating layer 170 and connected to a second source/drain region 150b, and a backside power structure 195 connected to the backside contact plug 190.

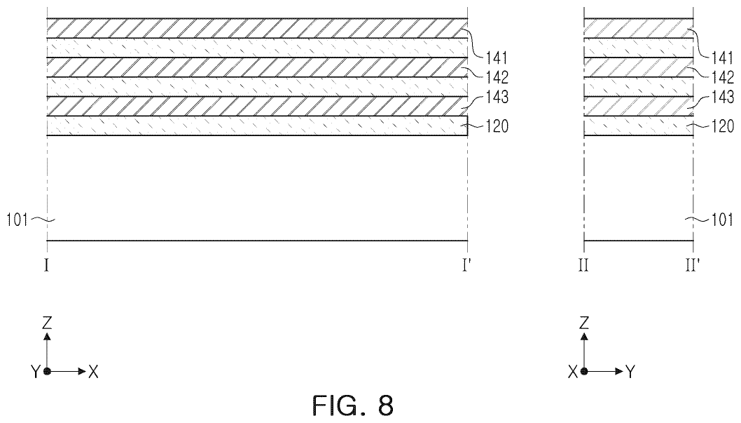

The substrate insulating layer 194 may have an upper surface extending in an X-direction and a Y-direction. The substrate insulating layer 194 may be a layer formed by removing and/or oxidizing a substrate 101 (see FIG. 8) formed of a semiconductor material during a manufacturing process. The substrate insulating layer 194 may be formed of an insulating material, and may include, for example, an oxide, a nitride, or a combination thereof. However, example embodiments are not limited thereto. According to some example embodiments, the substrate insulating layer 194 may include a plurality of insulating layers.

The gate structures 160 may be disposed to extend in one direction, for example, the Y-direction, on the substrate insulating layer 194. Channel regions of transistors may be formed in the channel structures 140 intersecting gate electrodes 165 of the gate structures 160. The gate structures 160 may be disposed to be spaced apart from each other in the X-direction. Each of the gate structures 160 may include gate dielectric layers 162, gate spacer layers 164, and a gate electrode 165. In some example embodiments, each of the gate structures 160 may further include a gate capping layer 167 on an upper surface of the gate electrode 165.

The gate dielectric layers 162 may be disposed between the substrate insulating layer 194 and the gate electrode 165 and between the channel structure 140 and the gate electrode 165, and may be disposed to cover at least a portion of surfaces of the gate electrode 165. For example, the gate dielectric layers 162 may be disposed to surround all surfaces except for an uppermost surface of the gate electrode 165. The gate dielectric layers 162 may extend between the gate electrode 165 and the gate spacer layers 164, but the inventive concepts are not limited thereto. The gate dielectric layers 162 may include an oxide, a nitride, or a high-K material. The high-K material may refer to a dielectric material having a higher dielectric constant than a silicon dioxide (SiO₂). The high-K material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). However, example embodiments are not limited thereto. According to some example embodiments, the gate dielectric layers 162 may be formed in a multilayer structure.

The gate electrode 165 may include a conductive material, and may include, for example, a metal nitride such as titanium nitride (TiN), tantalum nitride (TaN), or tungsten nitride (WN), and/or a metal material such as aluminum (Al), tungsten (W), molybdenum (Mo), or the like, or a semiconductor material such as doped polysilicon. However, example embodiments are not limited thereto. According to some example embodiments, the gate electrode 165 may be formed in a multilayer structure. In a region not illustrated, the gate electrodes 165 may be connected to upper contact plugs disposed thereon.

The gate spacer layers 164 may be disposed on both side surfaces of the gate electrode 165 on the channel structure 140. The gate spacer layers 164 may insulate the source/drain regions 150 and the gate electrodes 165. According to some example embodiments, shapes of upper ends of the gate spacer layers 164 may be variously changed, and the gate spacer layers 164 may be formed in a multilayer structure. The gate spacer layers 164 may include at least one of an oxide, a nitride, or an oxynitride, and may be formed as, for example, a low-K film. However, example embodiments are not limited thereto.

The gate capping layer 167 may extend in one direction on the gate electrode 165 and the gate spacer layers 164. The gate capping layer 167 may include at least one of an oxide, a nitride, or an oxynitride. However, example embodiments are not limited thereto.

The channel structures 140 may be disposed on the substrate insulating layer 194 to intersect the gate structures 160. Each of the channel structures 140 may include first to third channel layers 141, 142, and 143, which may be a plurality of, e.g., two or more channel layers spaced apart from each other in a Z-direction. The channel structures 140 may be connected to the source/drain regions 150. The channel structures 140 may have a width, equal to or substantially equal to a width of each of the gate structures 160 in the X-direction. In a cross-section in the Y-direction, among the first to third channel layers 141, 142, and 143, a channel layer arranged in a lower portion may have a width, equal to, substantially equal to, or greater than a width of a channel layer arranged in an upper portion. In some example embodiments, the channel structures 140 may have a reduced width compared to the gate structures 160, such that side surfaces are located below the gate structures 160 in the X-direction.

The channel structures 140 may be formed of a semiconductor material, and may include, for example, at least one of silicon (Si), silicon germanium (SiGe), or germanium (Ge). However, example embodiments are not limited thereto. The number and shapes of the channel layers forming one channel structure 140 may be changed in some example embodiments.

A first channel layer 141 located in an uppermost portion may be referred to as an uppermost channel layer 141, and a third channel layer 143 located in a lowermost portion may be referred to as a lowermost channel layer 143. In some example embodiments, when there are four channel layers, the lowermost channel layer may refer to a fourth channel layer located fourth from the uppermost portion.

In the semiconductor device 100, the gate electrode 165 may be disposed between the first to third channel layers 141, 142, and 143 of the channel structures 140 and on the channel structures 140. Therefore, the semiconductor device 100 may include a transistor having a multi bridge channel FET (MBCFET™) structure, which may be a gate-all-around type field effect transistor.

The source/drain regions 150 may be disposed at both sides of the gate structures 160 to contact the channel structures 140, respectively. The source/drain regions 150 may be connected to the channel structures 140. The source/drain regions 150 may be disposed to cover side surfaces of each of the first to third channel layers 141, 142, and 143 of the channel structure 140 in the X-direction. An upper surface of the source/drain region 150 may be located on a height level, equal to or substantially equal to a height level of a lower surface of the gate electrode 165 on the channel structure 140, and the height level may be variously changed in some example embodiments.

The source/drain regions 150 may include a first source/drain region 150a connected to the backside contact plug 190 and a second source/drain region 150b connected to the front side contact plug 180. The first source/drain region 150a and the second source/drain region 150b may be spaced apart from each other with the gate structure 160 therebetween. The source/drain regions 150 may be spaced apart from the substrate insulating layer 194 by the spacer layers 130. The first source/drain region 150a may be connected to the backside contact plug 190 through a lower surface or a lower end. A lower region of the first source/drain region 150a may have a shape recessed by the backside contact plug 190. The first source/drain region 150a may be electrically connected to the backside power structure 195 through the backside contact plug 190 and may receive power. The second source/drain region 150b may be connected to the front side contact plug 180 through an upper surface or an upper end. An upper region of the second source/drain region 150b may have a shape recessed by the front side contact plug 180. The first source/drain region 150a connected to the backside contact plug 190 may further include a backside epitaxial layer 155, unlike the second source/drain region 150b connected to the front side contact plug 180.

Each of the source/drain regions 150 may include first epitaxial layers 151 and second epitaxial layers 153. Hereinafter, the epitaxial layers included in the first source/drain region 150a may be described as a first epitaxial layer 151a and a second epitaxial layer 153a, and the epitaxial layers included in the second source/drain region 150b may be described as a first epitaxial layer 151b and a second epitaxial layer 153b, with different symbols. The first epitaxial layers 151 may cover side surfaces of each of the first to third channel layers 141, 142, and 143 in the X-direction, and may cover side surfaces of the gate structure 160 below the channel structure 140 in the X-direction. The first epitaxial layers 151 cover an internal side surface of each of the recessed regions in which the source/drain regions 150 are disposed, and may be disposed to be spaced apart from each other with the second epitaxial layer 153 therebetween within one source/drain region 150. The first epitaxial layers 151 may cover side surfaces of the channel structures 140 and the gate structure 160 in the X-direction. Lower ends of each of the first epitaxial layers 151 may be in contact with the spacer layers 130. The first epitaxial layer 151a of the first source/drain region 150a may be spaced apart from the backside contact plug 190, and the first epitaxial layer 151a of the second source/drain region 150b may be spaced apart from the front side contact plug 180. In some example embodiments, unlike those illustrated, the first epitaxial layers 151 may have external side surfaces protruding convexly from below the channel structures 140 toward the gate structures 160, and thus may have a curvature in the external side surfaces. Lower ends of the first epitaxial layers 151 may be in contact with the spacer layers 130.

The second epitaxial layer 153 may cover the first epitaxial layers 151, and may fill the recessed region. The second epitaxial layer 153 may be spaced apart from the channel structures 140 and the gate structure 160 by the first epitaxial layer 151. The second epitaxial layer 153a of the first source/drain region 150a may be spaced apart from the first spacer layer 130a by the backside epitaxial layer 155. The second epitaxial layer 153b of the second source/drain region 150b may be in contact with and connected to the front side contact plug 180.

The backside epitaxial layer 155 may be included in the first source/drain region 150a connected to the backside contact plug 190, and the second source/drain region 150b may not include the backside epitaxial layer 155, unlike the first source/drain region 150a. The backside epitaxial layer 155 may cover an upper portion of the backside contact plug 190. The backside epitaxial layer 155 may be disposed between the second epitaxial layer 153a of the first source/drain region 150a and the backside contact plug 190. The second epitaxial layer 153a of the first source/drain region 150a may be spaced apart from the backside contact plug 190 by the backside epitaxial layer 155. Since the first source/drain region 150a may include the backside epitaxial layer 155 contacting the backside contact plug 190, contact resistance of the backside contact plug 190 may be improved, and stress applied to adjacent channel structures 140 may increase to improve mobility of a channel.

The source/drain regions 150 may include a semiconductor material, for example, at least one of, but not limited to, silicon (Si) or germanium (Ge), and may further include impurities. In the present specification, the germanium (Ge) and the impurities may be referred to as a non-silicon element. The first epitaxial layer 151, the second epitaxial layer 153, and the backside epitaxial layer 155 may have different compositions. A concentration of the non-silicon element of the second epitaxial layer 153 may be greater than a concentration of the non-silicon element of the first epitaxial layer 151, and a concentration of the non-silicon element of the backside epitaxial layer 155 may be greater than the concentration of the non-silicon element of the second epitaxial layer 153. The concentration of the non-silicon element of the backside epitaxial layer 155 may be greater than a concentration of the non-silicon element of the second source/drain region 150b. In some example embodiments, the concentration of the non-silicon element of the first epitaxial layer 151 may be a first concentration, the concentration of the non-silicon element of the second epitaxial layer 153 may be a second concentration, the concentration of the non-silicon element of the backside epitaxial layer 155 may be a third concentration, the second concentration may be greater than the first concentration, and the third concentration may be greater than the second concentration. When the semiconductor device 100 is a pFET, the impurities may be, but are not limited to, at least one of boron (B), gallium (Ga), or indium (In), and when the semiconductor device 100 is an nFET, the impurities may be at least one of phosphorus (P), arsenic (As), or antimony (Sb). However, example embodiments are not limited thereto. For example, a boron (B) concentration of the first epitaxial layer 151 may be in a range of about 1×10¹⁶/cm³ to about 1×10²¹/cm³, and a boron (B) concentration of the second epitaxial layer 153 may be in a range of about 1×10¹⁹/cm³ to about 1×10²²/cm³. The boron (B) concentration of the backside epitaxial layer 155 may be greater than the boron (B) concentration of the second epitaxial layer 153, for example, in a range of about 1×10²⁰/cm³ to about 1×10²⁴/cm³.

When the semiconductor device 100 is a pFET, the source/drain regions 150 may include, but are not limited to, silicon germanium (SiGe), a germanium (Ge) concentration of the second epitaxial layer 153 may be greater than a germanium (Ge) concentration of the first epitaxial layer 151, and a germanium (Ge) concentration of the backside epitaxial layer 155 may be greater than the germanium (Ge) concentration of the second epitaxial layer 153. For example, the germanium (Ge) concentration of the first epitaxial layer 151 may be in a range of about 1 at % to about 20 at %, the germanium (Ge) concentration of the second epitaxial layer 153 may be in a range of about 30 at % to about 70 at %, and the germanium (Ge) concentration of the backside epitaxial layer 155 may be in a range of about 35 at % to about 80 at %.

The spacer layers 130 may be disposed below each of the source/drain regions 150. The spacer layers 130 may be in contact with a portion of the gate structure 160 below the lowermost channel layer 143. Upper ends of the spacer layers 130 may be located on a level, lower than a lower surface of the lowermost channel layer 143 and higher than a lower surface of the gate electrode 165. Lower ends of the spacer layers 130 may be located on a level, lower than the lower surface of the gate electrode 165. The spacer layers 130 may cover lower portions of the recessed regions at both sides of the gate structure 160. The spacer layers 130 may be in contact with the backside contact plug 190, and may surround a portion of the backside contact plug 190. The spacer layers 130 may include a first spacer layer 130a disposed below the first source/drain region 150a, and a second spacer layer 130b disposed below the second source/drain region 150b. The spacer layers 130 may include a different material from the source/drain regions 150. In some example embodiments, the spacer layers 130 may include an insulating material, for example, an oxide, a nitride, or a combination thereof. However, example embodiments are not limited thereto. For example, the spacer layers 130 may include silicon oxide, silicon nitride, or a combination thereof. In some example embodiments, the spacer layers 130 may include at least one of SIN, SiO, SiCN, SiOC, or SiOCN, or a combination thereof. However, example embodiments are not limited thereto. Since the semiconductor device 100 may include the spacer layers 130, the source/drain regions 150 may be protected during a process of removing the substrate 101 (see FIG. 8). A description related thereto will be described in detail in a description of a manufacturing method with reference to the drawings subsequent to FIG. 8.

The front side contact plug 180 may penetrate the interlayer insulating layer 170 and may be connected to the second source/drain region 150b, and may apply an electrical signal to the second source/drain region 150b. The front side contact plug 180 may recess the second source/drain region 150b from an upper surface, and may extend into the second source/drain region 150b. In some example embodiments, the front side contact plug 180 may extend below a lower surface of the uppermost channel layer 141. According to some example embodiments, the front side contact plug 180 may extend below a lower surface of the second channel layer 142, which may be a second channel layer from the upper surface. At least a portion of a side surface of the front side contact plug 180 may be inclined such that a width of the front side contact plug 180 decreases as a level thereof decreases. The front side contact plug 180 may include a metal material such as, for example, tungsten (W), cobalt (Co), molybdenum (Mo), copper (Cu), ruthenium (Ru), aluminum (Al), or the like. However, example embodiments are not limited thereto. The front side contact plug 180 may include, for example, a metal nitride such as titanium nitride (TiN), tantalum nitride (TaN), or tungsten nitride (WN), or may include a metal such as titanium (Ti), cobalt (Co), molybdenum (Mo), or platinum (Pt). However, example embodiments are not limited thereto. In some example embodiments, the front side contact plug 180 may include a metal-semiconductor compound layer, such as a metal silicide layer, disposed on an interface contacting the second epitaxial layer 153b.

The backside contact plug 190 may penetrate the substrate insulating layer 194 and the first spacer layer 130a, and may be connected to the first source/drain region 150a. The backside contact plug 190 may be partially recessed from a lower surface of the first source/drain region 150a, and may extend into the first source/drain region 150a. In some example embodiments, the backside contact plug 190 may extend above a lower surface of the lowermost channel layer 143. According to some example embodiments, the backside contact plug 190 may extend above an upper surface of the lowermost channel layer 143. The backside contact plug 190 may be in contact with the backside epitaxial layer 155 of the first source/drain region 150a, and may be spaced apart from the first epitaxial layer 151a and the second epitaxial layer 153a. At least a portion of a side surface of the backside contact plug 190 may be inclined such that a width of the backside contact plug 190 increases as a level thereof decreases. The backside contact plug 190 may include a metal material such as, for example, tungsten (W), cobalt (Co), molybdenum (Mo), copper (Cu), ruthenium (Ru), aluminum (Al), or the like. However, example embodiments are not limited thereto. The backside contact plug 190 may include a metal nitride, such as titanium nitride (TiN), tantalum nitride (TaN), or tungsten nitride (WN), or a metal, such as titanium (Ti), cobalt (Co), molybdenum (Mo), or platinum (Pt). However, example embodiments are not limited thereto. In some example embodiments, the backside contact plug 190 may include a metal-semiconductor compound layer, such as a metal silicide layer, disposed on an interface contacting the backside epitaxial layer 155.

The backside power structure 195 may be connected to a lower end or a lower surface of the backside contact plug 190. The backside power structure 195, together with the backside contact plug 190, may form a BSPDN for applying a power voltage or a ground voltage, and may also be referred to as a rear power rail or a buried power rail. For example, the backside power structure 195 may be a buried interconnection line extending in one direction, for example, in the X-direction, from a lower portion of the backside contact plug 190, but a shape of the backside power structure 195 is not limited thereto. For example, in some example embodiments, the backside power structure 195 may include a via region and/or a line region. In some example embodiments, unlike those illustrated, the backside power structure 195 may be a buried interconnection line extending in the Y-direction. A width of the backside power structure 195 may continuously increase in a downward direction, but the inventive concepts are not limited thereto. The backside power structure 195 may include a conductive material, for example, at least one of tungsten (W), copper (Cu), aluminum (Al), cobalt (Co), ruthenium (Ru), titanium (Ti), or molybdenum (Mo). However, example embodiments are not limited thereto.

The interlayer insulating layer 170 may be disposed to cover upper surfaces of the source/drain regions 150 and the gate structures 160. The interlayer insulating layer 170 may include at least one of an oxide, a nitride, or an oxynitride, and may include, for example, a low-K material. However, example embodiments are not limited thereto. According to some example embodiments, the interlayer insulating layer 170 may include a plurality of insulating layers.

The semiconductor device 100 may be packaged such that structures of FIGS. 2A and 2B are inverted such that the backside power structure 195 is located in an upper portion, but a packaging form of the semiconductor device 100 is not limited thereto. The source/drain regions 150 may be connected to the backside power structure 195 disposed below through the backside contact plug 190, such that a degree of integration may be improved. In addition, since the first source/drain region 150a connected to the backside contact plug 190 may include the backside epitaxial layer 155 having a high concentration, electrical characteristics may be improved, and since the spacer layers 130 may be included below each of the source/drain regions 150, the source/drain regions 150 may be protected to improve reliability of the semiconductor device.

In the description of some example embodiments below, any description overlapping the description described above with reference to FIGS. 1 to 2C will be omitted.

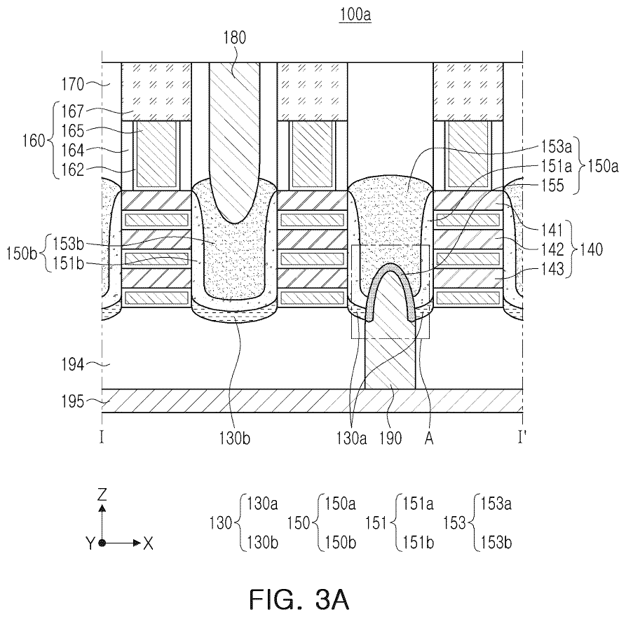

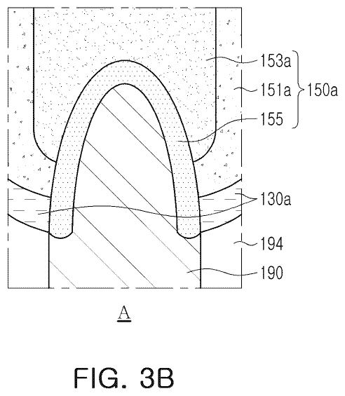

FIG. 3A is a schematic cross-sectional view illustrating a semiconductor device according to some example embodiments. FIG. 3A illustrates a cross-sectional view corresponding to FIG. 2A.

FIG. 3B is a schematic enlarged view illustrating a semiconductor device according to some example embodiments. FIG. 3B may be an enlarged view of portion ‘A’ of FIG. 3A.

Referring to FIGS. 3A and 3B, unlike the semiconductor device 100 of FIG. 2A to FIG. 2C, in a semiconductor device 100a, first epitaxial layers 151 included in each of source/drain regions 150 may cover upper surfaces of spacer layers 130, and second epitaxial layers 153 may be spaced apart from the spacer layers 130. A first epitaxial layer 151a of a first source/drain region 150a may surround a portion of a backside contact plug 190. A backside epitaxial layer 155 may extend between a first spacer layer 130a and the backside contact plug 190, and the first spacer layer 130a may be spaced apart from the backside contact plug 190. In some example embodiments, the spacer layers 130 may include at least one of silicon (Si) or germanium (Ge). However, example embodiments are not limited thereto. According to some example embodiments, the spacer layers 130 may further include impurities. A concentration of a non-silicon element included in each of the spacer layers 130 may be equal to, substantially equal to, or greater than a concentration of a non-silicon element included in each of the first epitaxial layers 151, and may be less than a concentration of a non-silicon element included in each of the second epitaxial layers 153. Depending on a material included in the spacer layers 130, a shape in which the first epitaxial layers 151 are formed may be modified. In the semiconductor device 100a, the spacer layers 130 may include a material on which the first epitaxial layers 151 may grow, and accordingly, a shape of the first epitaxial layer 151 may be different from a shape of the first epitaxial layer 151 of FIGS. 2A to 2C. In the semiconductor device 100a, when the spacer layers 130 include germanium (Ge), mobility of channel structures 140 may be improved by applying stress to the channel structures 140.

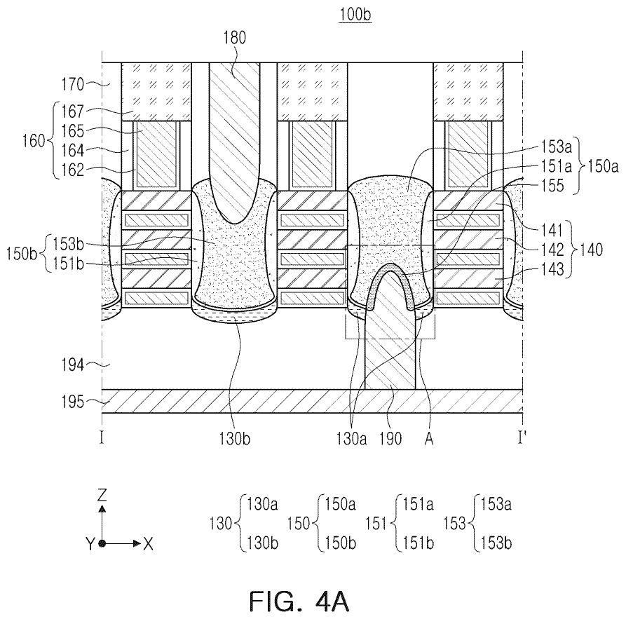

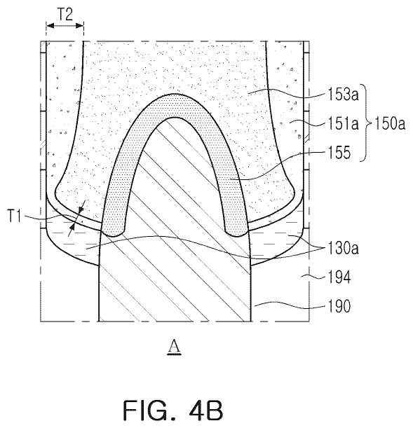

FIG. 4A is a schematic cross-sectional view illustrating a semiconductor device according to some example embodiments. FIG. 4A illustrates a cross-sectional view corresponding to FIG. 2A.

FIG. 4B is a schematic enlarged view illustrating a semiconductor device according to some example embodiments. FIG. 4B may be an enlarged view of portion ‘A’ of FIG. 4A.

Referring to FIGS. 4A and 4B, unlike the semiconductor device 100a of FIGS. 3A to 3B, in a first epitaxial layer 151a of a semiconductor device 100b, a first thickness TI formed on spacer layers 130 may be smaller than a second thickness T2 formed on side surfaces of a channel structure 140 and a gate structure 160. In some example embodiments, the spacer layers 130 may include an insulating material such as an oxide, a nitride, or the like, as in the semiconductor device 100 of FIGS. 1 to 2C, but may include at least one of silicon (Si) or germanium (Ge), and may further include a non-silicon element, as in the semiconductor device 100a of FIGS. 3A to 3B. However, example embodiments are not limited thereto. In the semiconductor device 100b, a first epitaxial layer 151 may be partially formed on the spacer layers 130, but a degree of epitaxial growth thereof may be less than that of the semiconductor device 100a of FIGS. 3A to 3B.

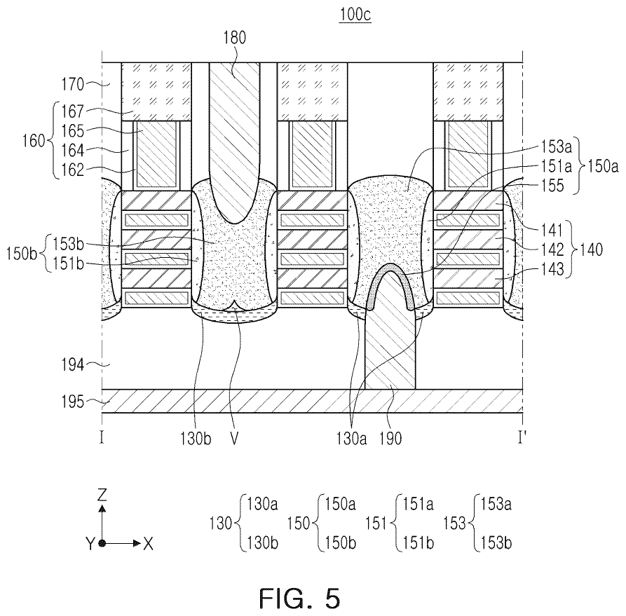

FIGS. 5 to 7 are schematic cross-sectional views illustrating semiconductor devices according to some example embodiments. FIGS. 5 to 7 illustrate cross-sectional views corresponding to FIG. 2A.

Referring to FIG. 5, unlike the semiconductor device 100 of FIGS. 2A to 2C, a void V may exist in a lower portion of a second source/drain region 150b connected to a front side contact plug 180 in a semiconductor device 100c. The void V may be in contact with a second spacer layer 130b, and may be small enough not to affect channel stress. In some example embodiments, even when the void V exists in the second source/drain region 150b, the second source/drain region 150b may be connected to the front side contact plug 180.

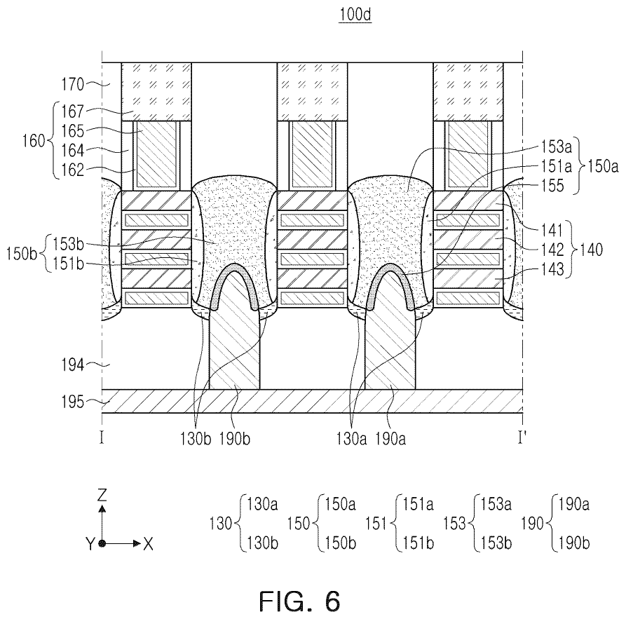

Referring to FIG. 6, unlike the semiconductor device 100 of FIGS. 2A to 2C, in a semiconductor device 100d, a second source/drain region 150b may be connected to a backside contact plug 190b. Source/drain regions 150 at both sides of one gate structure 160 may be connected to a backside contact plug 190. Depending on a design purpose, whether the second source/drain region 150b is connected to a front side contact plug 180 or the backside contact plug 190 may be variously modified. Unlike the semiconductor device 100c of FIG. 5, a void V may not exist in the second source/drain region 150b connected to the backside contact plug 190b. In this case, the void V may not have been formed from the beginning, or may have been removed during a process of forming the backside contact plug 190b after it was formed.

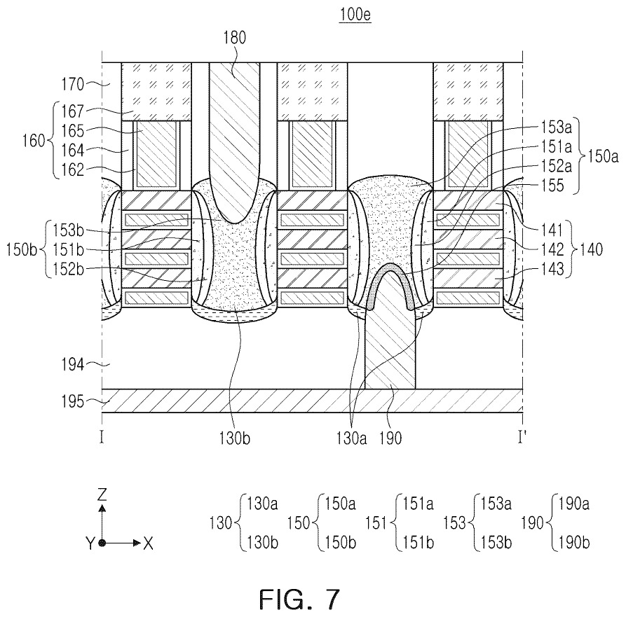

Referring to FIG. 7, unlike the semiconductor device 100 of FIGS. 2A to 2C, in a semiconductor device 100e, an intermediate epitaxial layer 152 may be disposed on a first epitaxial layer 151. The intermediate epitaxial layer 152 may be disposed between the first epitaxial layer 151 and a second epitaxial layer 153. A concentration of a non-silicon element included in the intermediate epitaxial layer 152 may be greater than a concentration of a non-silicon element included in the first epitaxial layer 151, and may be less than a concentration of a non-silicon element included in the second epitaxial layer 153. As the intermediate epitaxial layer 152 is included, the second epitaxial layer 153 may be further separated from a channel structure 140 and a gate structure 160 below an uppermost channel layer 141.

FIGS. 8 to 21 are views illustrating a process sequence illustrating a method of manufacturing a semiconductor device according to some example embodiments. The drawings illustrate drawings corresponding to FIGS. 2A and 2B.

Referring to FIG. 8, sacrificial layers 120 and first to third channel layers 141, 142, and 143 may be alternately stacked on a substrate 101.

The substrate 101 may include silicon (Si), germanium (Ge), or silicon germanium (SiGe). The substrate 101 may include a bulk wafer, an epitaxial layer, a silicon-on-insulator (SOI) layer, or a semiconductor-on-insulator (SeOI) layer. However, example embodiments are not limited thereto.

The sacrificial layers 120 may be layers that may be replaced with gate dielectric layers 162 and gate electrodes 165 below the first channel layer 141 by a subsequent process, as illustrated in FIGS. 2A and 2B. The sacrificial layers 120 may be formed of a material having etching selectivity with respect to the first to third channel layers 141, 142, and 143, respectively. The first to third channel layers 141, 142, and 143 may include a material, different from the sacrificial layers 120. The sacrificial layers 120 and the first to third channel layers 141, 142, and 143 may include, for example, a semiconductor material including at least one of silicon (Si), silicon germanium (SiGe), or germanium (Ge), but may include different materials and may or may not include impurities. For example, the sacrificial layers 120 may include silicon germanium (SiGe), and the first to third channel layers 141, 142, and 143 may include silicon (Si). However, example embodiments are not limited thereto.

The sacrificial layers 120 and the first to third channel layers 141, 142, and 143 may be formed by performing an epitaxial growth process from the stacked structure. The number of layers of channel layers alternately stacked with the sacrificial layers 120 may be changed in some example embodiments.

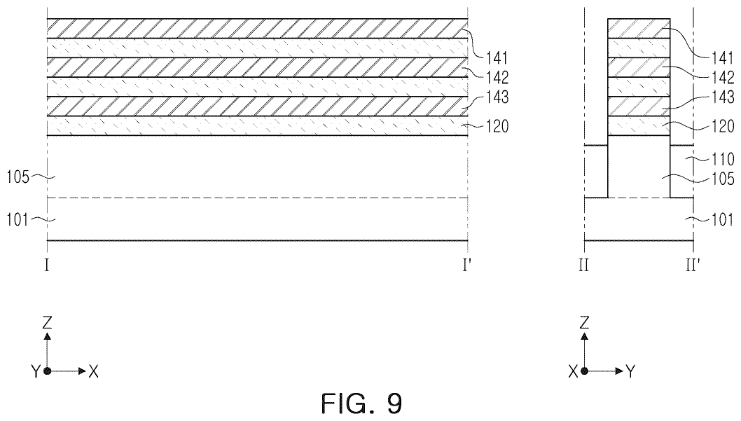

Referring to FIG. 9, the sacrificial layers 120, the first to third channel layers 141, 142, and 143, and the substrate 101 may be partially removed to form an active structure including an active region 105, and to form a device isolation layer 110.

The active structure may include the active region 105, the sacrificial layers 120, and the first to third channel layers 141, 142, and 143. The active structure may be formed in a linear shape extending in one direction, for example, the X-direction, and may be formed spaced apart from an adjacent active structure in the Y-direction. Side surfaces of the active structure in the Y-direction may be coplanar and/or substantially coplanar with each other, and may be located on a straight line.

In a region in which the active region 105, the sacrificial layers 120, and a portion of each of the first to third channel layers 141, 142, and 143 may be removed, an insulating material may be filled in and then the device isolation layer 110 may be formed by removing a portion of the insulating material such that the active region 105 protrudes. An upper surface of the device isolation layer 110 may be formed lower than an upper surface of the active region 105.

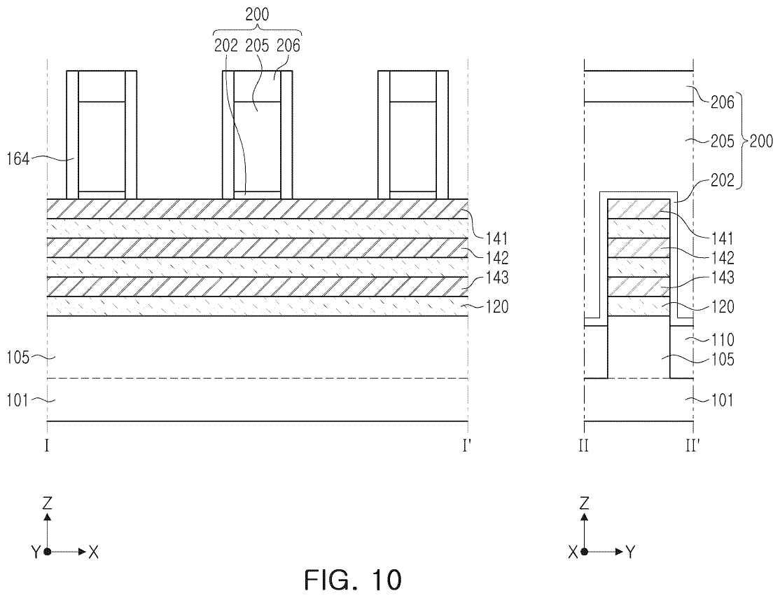

Referring to FIG. 10, sacrificial gate structures 200 and gate spacer layers 164 may be formed on the active structure.

The sacrificial gate structures 200 may be sacrificial structures formed in a region in which gate dielectric layers 162 and gate electrodes 165 are disposed on channel structures 140 by a subsequent process, as illustrated in FIG. 2. The sacrificial gate structures 200 may have a linear shape extending in one direction while intersecting the active structure. The sacrificial gate structures 200 may extend in the Y-direction, for example, and may be disposed to be spaced apart from each other in the X-direction.

The sacrificial gate structures 200 may include first and second sacrificial gate layers 202 and 205 and a mask pattern layer 206, sequentially stacked. The first and second sacrificial gate layers 202 and 205 may be patterned using the mask pattern layer 206. The first and second sacrificial gate layers 202 and 205 may be an insulating layer and a conductive layer, respectively, but the inventive concepts are not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride. However, example embodiments are not limited thereto.

The gate spacer layers 164 may be formed on both sidewalls of the sacrificial gate structures 200. The gate spacer layers 164 may be formed of a low-K material, and may include, for example, at least one of SiO, SiN, SiCN, SiOC, SiON, or SiOCN. However, example embodiments are not limited thereto.

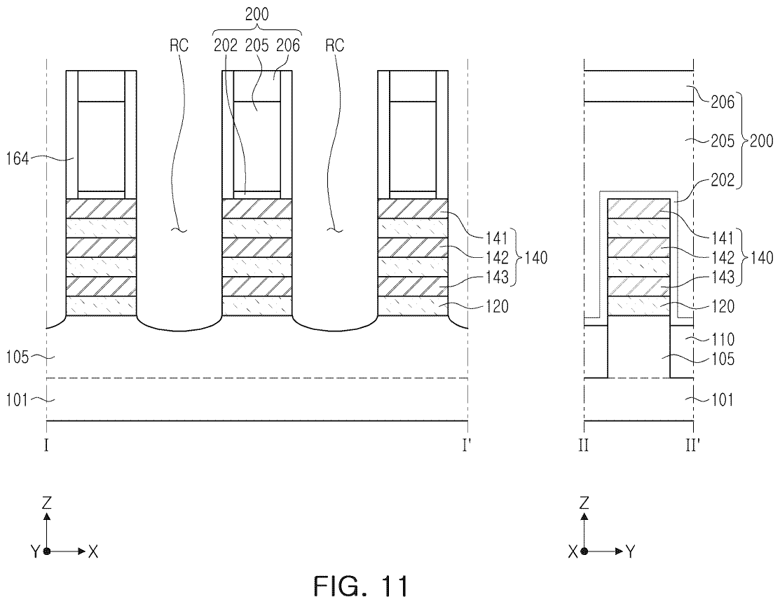

Referring to FIG. 11, the sacrificial layers 120 and the first to third channel layers 141, 142, and 143, exposed from the sacrificial gate structures 200, may be partially removed to form recess regions RC, and the sacrificial layers 120 may be partially removed.

Using the sacrificial gate structures 200 and the gate spacer layers 164 as masks, the exposed sacrificial layers 120 and the first to third channel layers 141, 142, and 143 may be partially removed to form the recess regions RC. As a result, the first to third channel layers 141, 142, and 143 may form channel structures 140 having a limited length in the X-direction.

Specific shapes of side surfaces of the sacrificial layers 120 are not limited to that illustrated in FIG. 11. In some example embodiments, the sacrificial layers 120 may be selectively etched with respect to the channel structures 140 by, for example, a wet etching process, to be removed from the side surfaces in the X-direction by a desired (and/or alternatively predetermined) depth. In this case, unlike the illustrated example embodiments, the sacrificial layers 120 may have concave side surfaces inwardly by side etching, as described above.

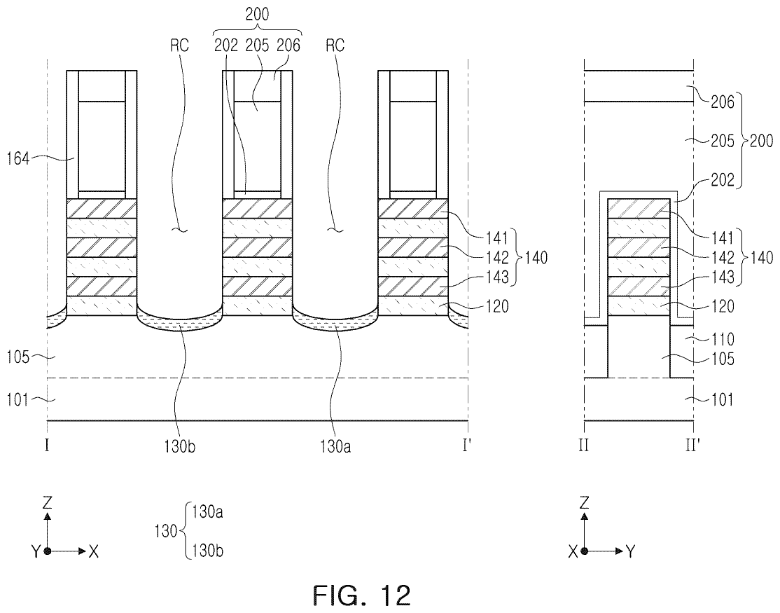

Referring to FIG. 12, spacer layers 130 may be formed in the recessed regions RC. The spacer layers 130 may cover upper surfaces of the active region 105 exposed by the recessed regions RC, and may partially cover the sacrificial layers 120 below a lowermost channel layer 143. The spacer layers 130 may include an insulating material, and may be formed by depositing an insulating material in a vertical direction and then etching a remaining portion, or by forming a mask layer and then depositing an insulating material.

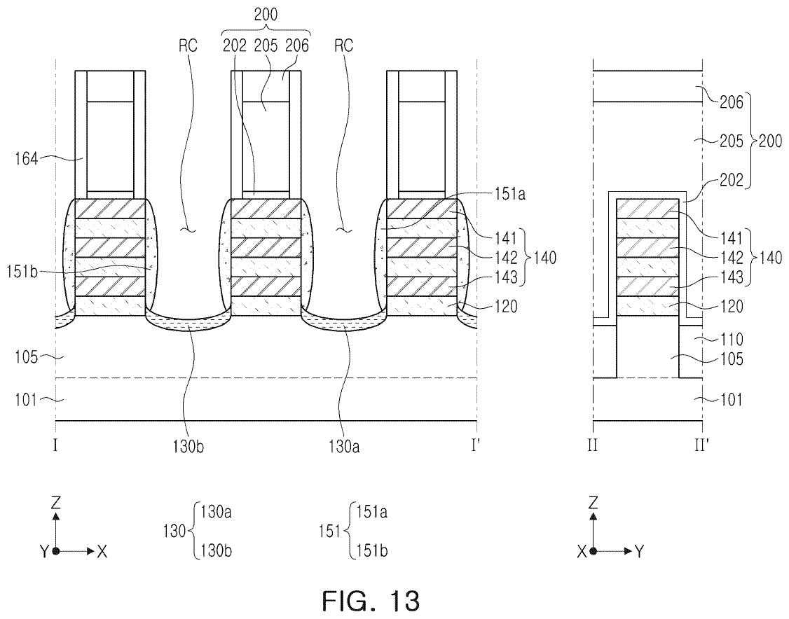

Referring to FIG. 13, first epitaxial layers 151 covering side surfaces of the channel structure 140 and the sacrificial layers 120 may be formed in the recess region RC. The first epitaxial layers 151 may be formed by, for example, growing by a selective epitaxial process. The first epitaxial layers 151 may be grown on the side surfaces of the channel structure 140 and the sacrificial layers 120 formed by the recess region RC, and may not be grown on the spacer layers 130, or may be grown to a relatively small extent. The first epitaxial layers 151 may cover a portion of the spacer layers 130. In some example embodiments, the first epitaxial layers 151 may include silicon germanium (SiGe), and a concentration of germanium (Ge) included in the first epitaxial layer 151 may be less than a concentration of germanium (Ge) included in the sacrificial layers 120, and the first epitaxial layer 151 may have etch selectivity with respect to the sacrificial layers 120.

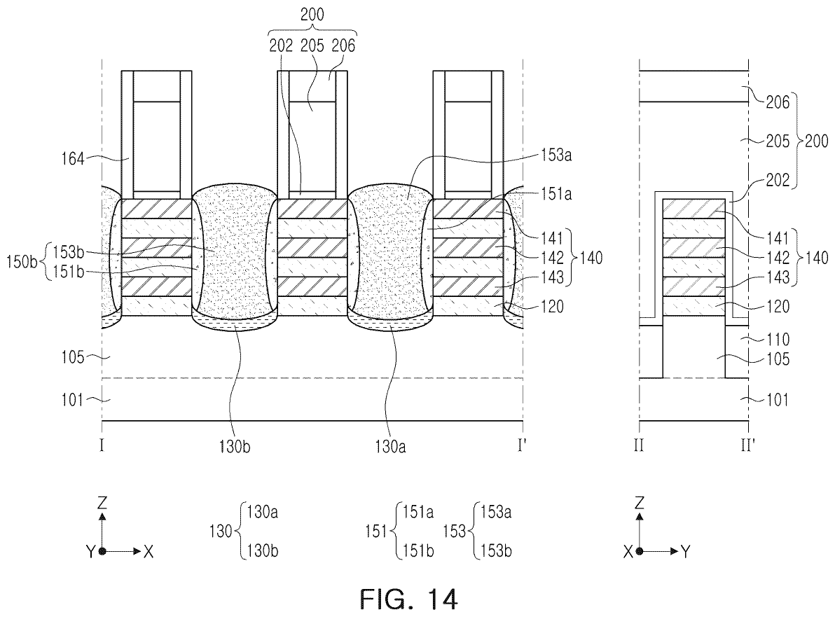

Referring to FIG. 14, a second epitaxial layer 153 may be formed to fill the recess region RC. The second epitaxial layer 153 may be formed by growing, for example, by a selective epitaxial process. The second epitaxial layer 153 may be grown on the first epitaxial layer 151, and may not be grown on the spacer layers 130, or may be grown to a relatively small extent. The second epitaxial layer 153 may be grown on the first epitaxial layer 151 to fill the recess region RC.

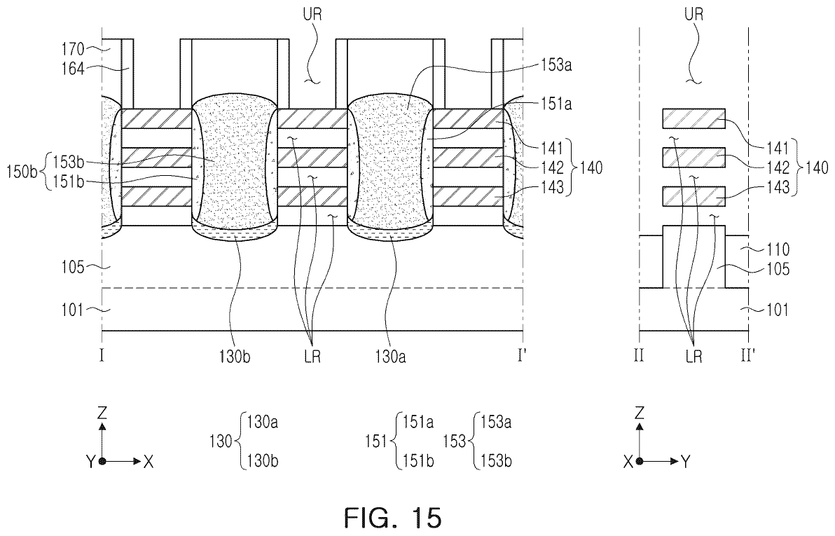

Referring to FIG. 15, an interlayer insulating layer 170 may be partially formed, and the sacrificial gate structures 200 and the sacrificial layers 120 may be removed.

The interlayer insulating layer 170 may be formed by forming an insulating film covering the sacrificial gate structures 200 and the source/drain regions 150 and performing a planarization process.

The sacrificial gate structures 200 and the sacrificial layers 120 may be selectively removed with respect to the gate spacer layers 164, the interlayer insulating layer 170, and the channel structures 140. First, the sacrificial gate structures 200 may be removed to form upper gap regions UR, and then the sacrificial layers 120 exposed through the upper gap regions UR may be removed to form lower gap regions LR.

For example, when the sacrificial layers 120 include silicon germanium (SiGe) and the channel structures 140 include silicon (Si), the sacrificial layers 120 may be selectively removed with respect to the channel structures 140 by performing a wet etching process. For example, when the sacrificial layers 120 include a relatively high concentration of germanium (Ge) and the first epitaxial layer 151 includes a relatively low concentration of germanium (Ge), the sacrificial layers 120 may be selectively removed with respect to the first epitaxial layer 151. The second epitaxial layer 153 may be protected by the first epitaxial layer 151 and the spacer layers 130.

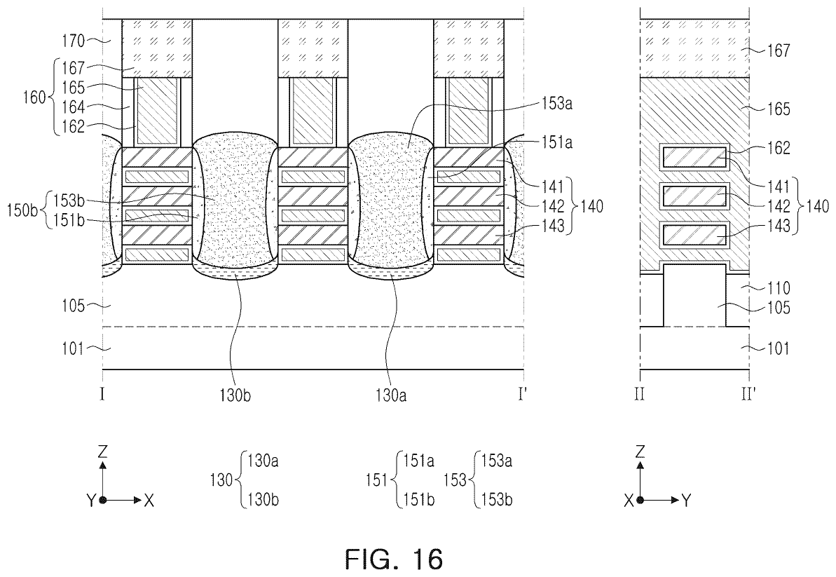

Referring to FIG. 16, gate dielectric layers 162 and gate electrodes 165 may be formed to form gate structures 160. The gate dielectric layers 162 and the gate electrodes 165 may be formed to fill the upper gap regions UR and the lower gap regions LR. The gate dielectric layers 162 may be formed to conformally cover inner surfaces of the upper gap regions UR and the lower gap regions LR. After the gate electrode 165 is formed to completely fill the upper gap regions UR and the lower gap regions LR, the gate electrode 165 may be removed from an upper portion in the upper gap regions UR by a desired (and/or alternatively predetermined) depth, together with the gate dielectric layers 162 and the gate spacer layers 164. Thereafter, a gate capping layer 167 may be further formed on the gate structures 160.

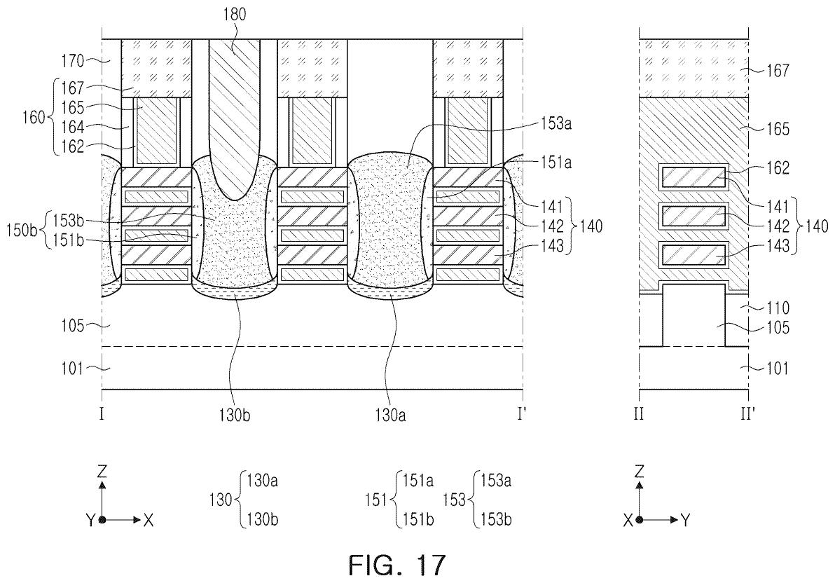

Referring to FIG. 17, a front side contact plug 180 penetrating the interlayer insulating layer 170 and connected to the second source/drain region 150b may be formed. The front side contact plug 180 may be formed by penetrating the interlayer insulating layer 170 and partially etching the second source/drain region 150b from an upper portion to form a hole, and then filling the hole with a conductive material. In some example embodiments, a metal-semiconductor compound layer may be formed on the second source/drain region 150b exposed by the hole, and then the front side contact plug 180 including the metal-semiconductor compound layer may be formed.

Although not specifically illustrated, metal wires and an upper insulating layer covering the metal wires may be formed on an upper portion of the front side contact plug 180.

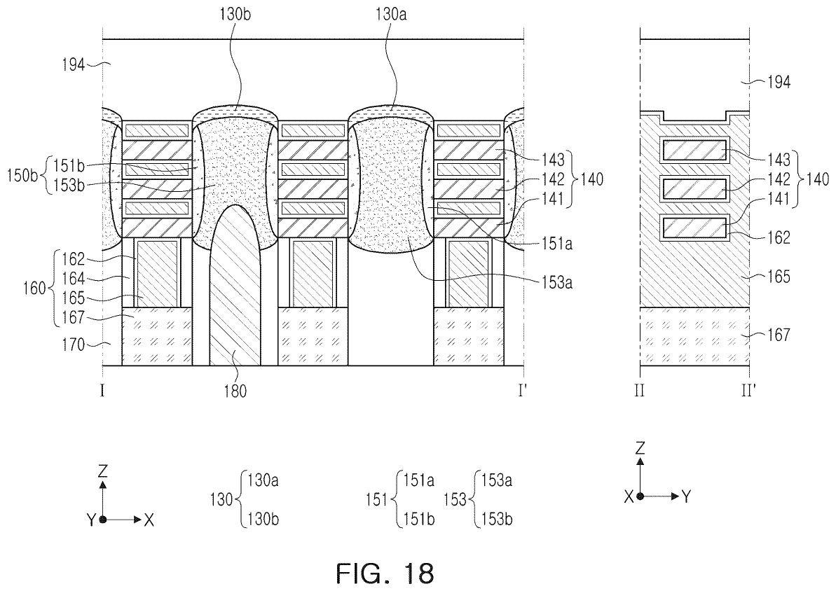

Referring to FIG. 18, the entire structure formed with reference to FIGS. 8 to 17 may be attached to a carrier substrate, the substrate 101, the active region 105, and the device isolation layer 110 may be removed, and a substrate insulating layer 194 may be formed. In the drawings subsequent to FIG. 18, the entire structure is illustrated as being rotated or flipped in a mirror image form of the structure illustrated in FIG. 17 for better understanding.

The substrate 101 may be removed from the upper surface of the substrate 101. The substrate 101 may be removed by, for example, a lapping process, a grinding process, or a polishing process, to be thinned, and a remaining region may also be removed by an etching process and/or an oxidation process. A thickness of the substrate 101 removed may be changed in some example embodiments. In some example embodiments, the substrate 101 may not be completely removed, and may remain partially. In this case, the active region 105 may remain on an uppermost surface of the gate structures 160. In this process, the source/drain regions 150 may be protected by the spacer layers 130.

The substrate insulating layer 194 may be formed in a region from which the substrate 101 is removed. When a portion of the device isolation layer 110 is not removed together with the substrate 101 and remains, the substrate insulating layer 194 may include a remaining portion of the device isolation layer 110.

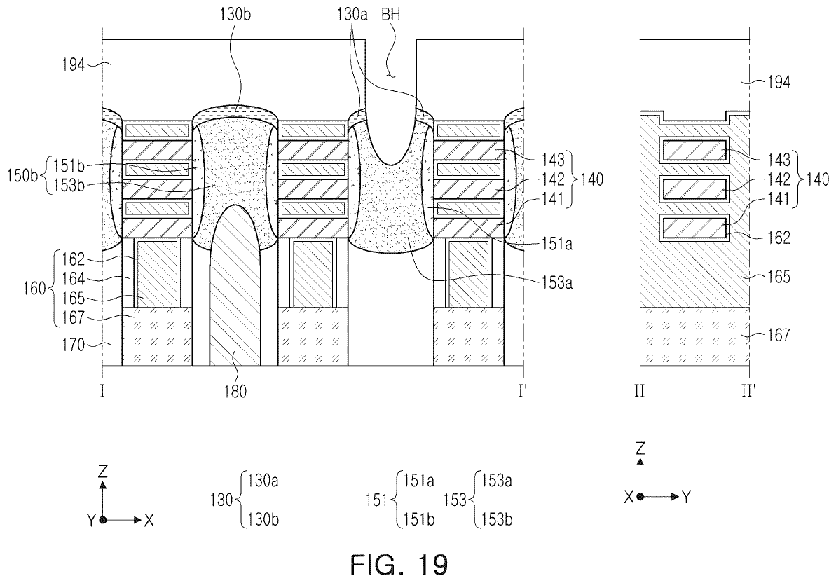

Referring to FIG. 19, a backside contact hole BH penetrating the substrate insulating layer 194 and the first spacer layer 130a and extending into the first source/drain region 150a may be formed. In some example embodiments, the backside contact hole BH may extend below a lower surface (based on FIG. 19) of the third channel layer 143.

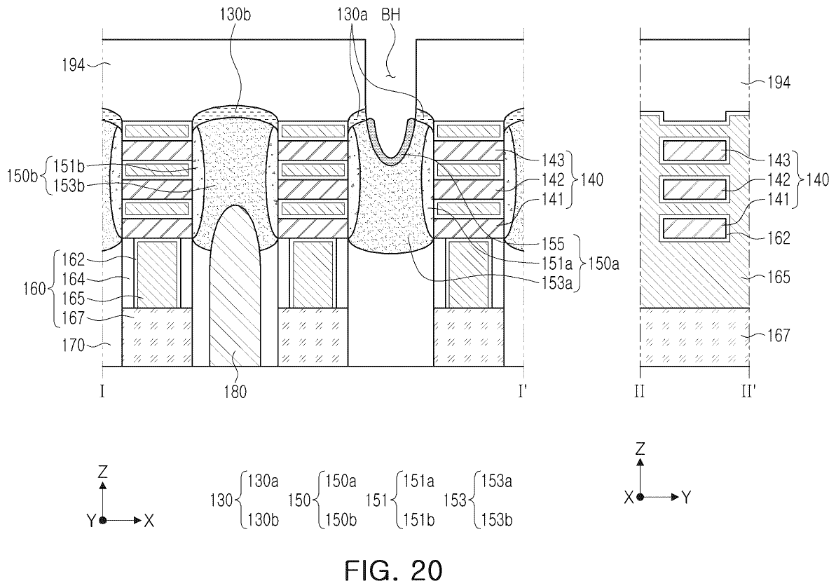

Referring to FIG. 20, a backside epitaxial layer 155 may be formed on a second epitaxial layer 153a exposed by the backside contact hole BH. The backside epitaxial layer 155 may be formed by growing, for example, in a selective epitaxial process. The backside epitaxial layer 155 may be grown on the second epitaxial layer 153a, and may not be grown on the first spacer layer 130a and the substrate insulating layer 194, or may be grown at a relatively low speed. As the substrate 101 of the existing FIGS. 8 to 17 is removed and replaced with the substrate insulating layer 194, the backside epitaxial layer 155 may be grown only from the second epitaxial layer 153a during the selective epitaxial process of the backside epitaxial layer 155. The backside epitaxial layer 155 may cover entirely an exposed portion of the second epitaxial layer 153a exposed by the backside contact hole BH. A concentration of a non-silicon element of the backside epitaxial layer 155 may be greater than a concentration of a non-silicon element of the second epitaxial layer 153a.

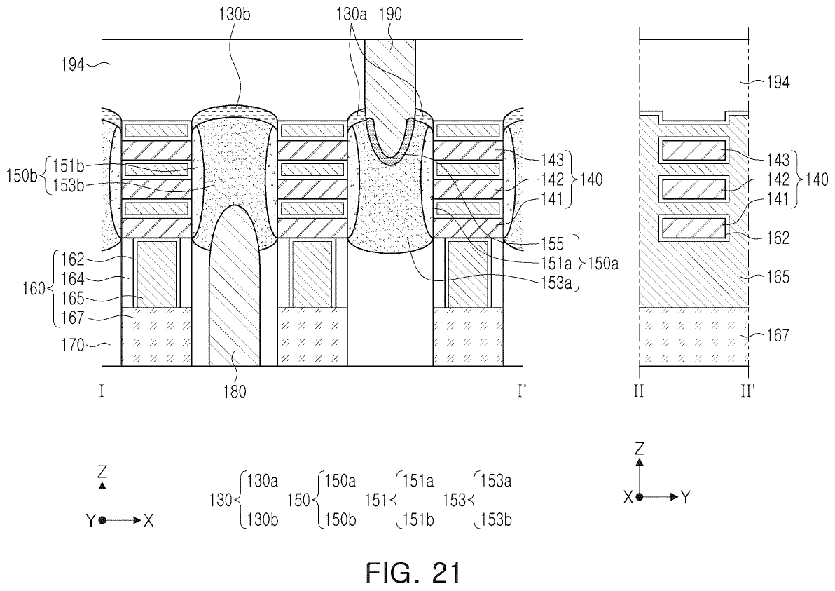

Referring to FIG. 21, a conductive material may be formed in the backside contact hole BH to form a backside contact plug 190. In some example embodiments, a metal-semiconductor compound layer may be formed on the backside epitaxial layer 155, and then the backside contact plug 190 including a metal-semiconductor compound layer may be formed. Referring to FIGS. 2A and 2B together, a backside power structure 195 connected to the backside contact plug 190 may be formed, such that the semiconductor device of FIGS. 2A to 2C is manufactured.

In the following description of a semiconductor manufacturing method, any description overlapping with the description referring to FIGS. 8 to 21 will be omitted.

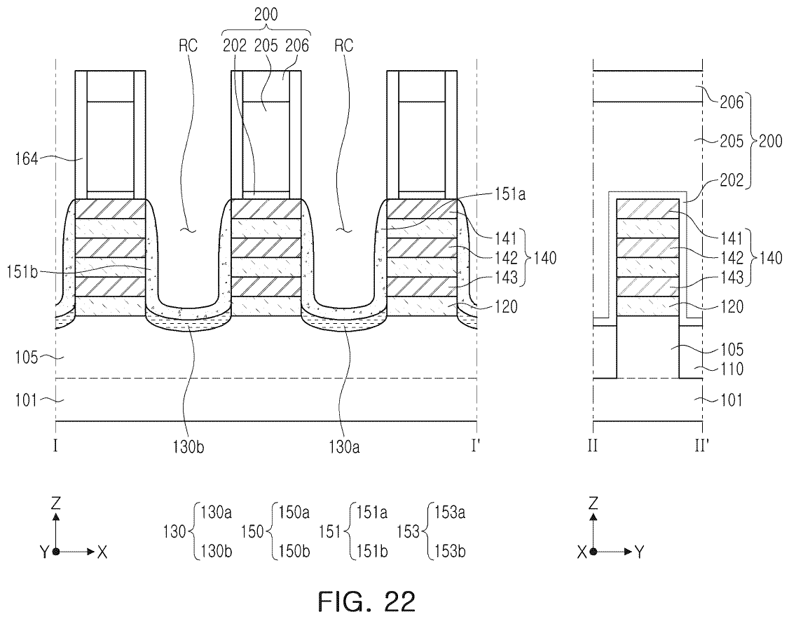

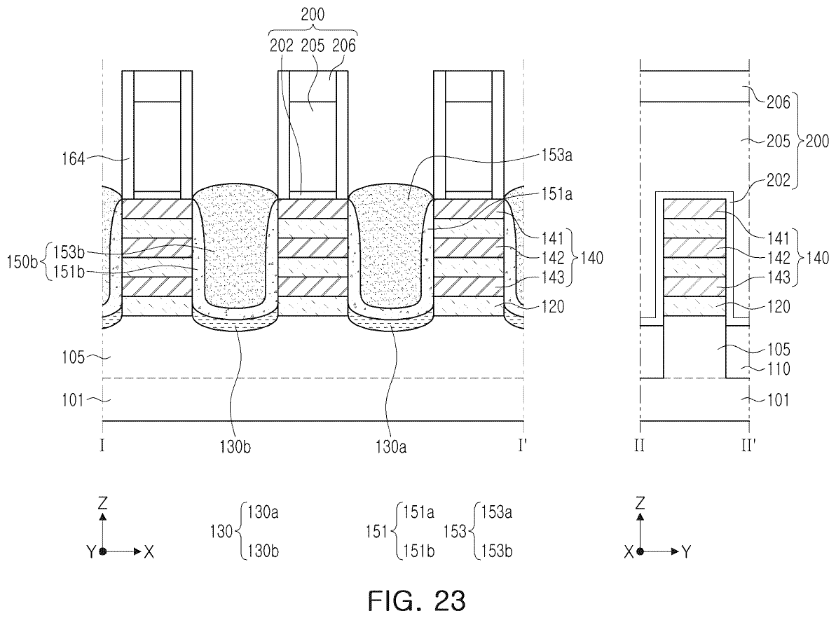

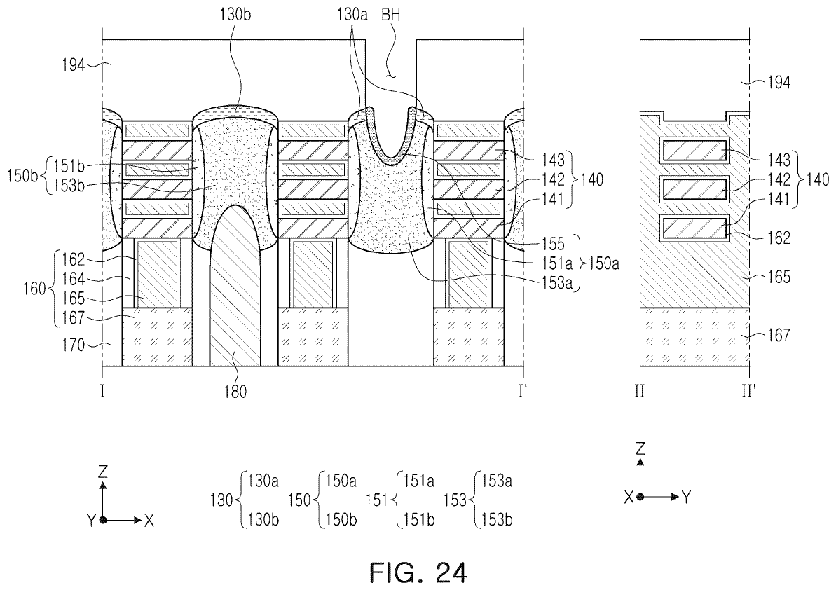

FIGS. 22 to 24 are views illustrating a process sequence illustrating a method of manufacturing a semiconductor device according to some example embodiments. The drawings illustrate drawings corresponding to FIG. 3A. FIGS. 22 and 23 illustrate process operations corresponding to FIGS. 13 and 14, respectively, and FIG. 24 illustrates process operations corresponding to FIG. 20.

Referring to FIG. 22, unlike the process of FIG. 13, a first epitaxial layer 151 may also be grown on spacer layers 130. The first epitaxial layer 151 may cover not only side surfaces of channel structures 140 and side surfaces of sacrificial layers 120, but also the spacer layers 130. The spacer layers 130 may include at least one of silicon (Si) or germanium (Ge), and the first epitaxial layer 151 may also be grown on the spacer layers 130 by a selective epitaxial process.

Referring to FIG. 23, a second epitaxial layer 153 may be formed to fill the recess region RC. Unlike the process of FIG. 14, the second epitaxial layer 153 may be spaced apart from the spacer layers 130 by the first epitaxial layer 151.

Referring to FIG. 24, unlike the process of FIG. 20, growth of a backside epitaxial layer 155 may also proceed on a first spacer layer 130a. Therefore, the backside epitaxial layer 155 may cover not only the second epitaxial layer 153a but also the first spacer layer 130a, and the semiconductor device 100a of FIGS. 3A to 3B may be manufactured by a subsequent process.

A spacer layer below a source/drain region may be included to protect the source/drain region during a manufacturing process, and a backside epitaxial layer may be included in an end portion of a backside contact plug to reduce contact resistance, to provide a semiconductor device having improved reliability.

Various advantages and effects of the inventive concepts are not limited to the above-described contents, and will be more easily understood in the process of describing specific embodiments.

While some example embodiments have been illustrated and described above, it will be apparent to those skilled in the art that modifications and variations could be made without departing from the scope of the inventive concepts as defined by the appended claims.

What is claimed is:

1. A semiconductor device comprising:
a substrate insulating layer;
a gate structure extending in a first direction on the substrate insulating layer;
a plurality of channel layers spaced apart from each other in a second direction, the second direction perpendicular to an upper surface of the substrate insulating layer;
the plurality of channel layers on the substrate insulating layer and surrounded by the gate structure;
a first source/drain region and a second source/drain region, on both sides of the gate structure and connecting to the plurality of channel layers;
a first spacer layer below the first source/drain region, and a second spacer layer below the second source/drain region; and
a backside contact plug partially recessing a lower surface of the first source/drain region through the substrate insulating layer and the first spacer layer,
wherein each of the first and second source/drain regions includes
a first epitaxial layer covering side surfaces of the plurality of channel layers, and
a second epitaxial layer on the first epitaxial layer,
the first source/drain region includes
a backside epitaxial layer covering an upper portion of the backside contact plug, and
a concentration of a non-silicon element included in the backside epitaxial layer is greater than a concentration of a non-silicon element included in the second epitaxial layer.

2. The semiconductor device of claim 1, wherein the non-silicon element is at least one of germanium (Ge), boron (B), gallium (Ga), indium (In), phosphorus (P), arsenic (As), or antimony (Sb).

3. The semiconductor device of claim 1, wherein the first and second spacer layers comprise materials, different from materials of the first and second epitaxial layers.

4. The semiconductor device of claim 3, wherein the first and second spacer layers comprise at least one of SiN, SiO, SiCN, SiOC, or SiOCN.

5. The semiconductor device of claim 1, wherein the backside epitaxial layer is between the second epitaxial layer and the backside contact plug.

6. The semiconductor device of claim 1, wherein the first and second epitaxial layers of the first source/drain region are spaced apart from the backside contact plug.

7. The semiconductor device of claim 1, wherein the plurality of channel layers comprise a lowermost channel layer in a lowermost portion, and
wherein upper ends of the first and second spacer layers are on a level lower than a lower surface of the lowermost channel layer.

8. The semiconductor device of claim 1, wherein
the gate structure comprises
a gate electrode surrounding the plurality of channel layers,
gate dielectric layers between the gate electrode and the plurality of channel layers, and
gate dielectric layers further between the gate electrode and the substrate insulating layer,
wherein upper ends of the first and second spacer layers are on a level, higher than a lower surface of the gate electrode.

9. The semiconductor device of claim 1, further comprising a front side contact plug partially recessing an upper surface of the second source/drain region.

10. The semiconductor device of claim 1, wherein
a lower end of the first epitaxial layer of the first source/drain region is in contact with the first spacer layer, and
a lower end of the first epitaxial layer of the second source/drain region is in contact with the second spacer layer.

11. The semiconductor device of claim 1, wherein the first and second source/drain regions are spaced apart from the substrate insulating layer.

12. The semiconductor device of claim 1, further comprising a void on the second spacer layer in the second source/drain region.

13. A semiconductor device comprising:
a gate structure extending in one direction;
a source/drain region on a side of the gate structure;
a backside contact plug connecting to the source/drain region from below the source/drain region; and
a spacer layer surrounding at least a portion of the backside contact plug below the source/drain region,
wherein the source/drain region includes
a first epitaxial layer contacting the gate structure,
a second epitaxial layer on the first epitaxial layer, and
a backside epitaxial layer between the second epitaxial layer and the backside contact plug,
wherein
the first epitaxial layer includes a non-silicon element having a first concentration,
the second epitaxial layer includes a non-silicon element having a second concentration, the second concentration greater than the first concentration, and
the backside epitaxial layer includes a non-silicon element having a third concentration, the third concentration greater than the second concentration.

14. The semiconductor device of claim 13, wherein the first and second epitaxial layers are spaced apart from the backside contact plug.

15. The semiconductor device of claim 14, wherein the spacer layer comprises at least one of silicon oxide, silicon nitride, or silicon oxynitride.

16. The semiconductor device of claim 13, wherein
the source/drain region further comprises an intermediate epitaxial layer between the first epitaxial layer and the second epitaxial layer, and
the intermediate epitaxial layer includes a non-silicon element having a fourth concentration, the fourth concentration greater than the first concentration and less than the second concentration.

17. The semiconductor device of claim 13, wherein
the first epitaxial layer covers the spacer layer and surrounds at least a portion of the backside contact plug, and
the second epitaxial layer is spaced apart from the spacer layer.

18. The semiconductor device of claim 17, wherein the spacer layer comprises at least one of silicon (Si) or germanium (Ge).

19. A semiconductor device comprising:
a substrate insulating layer;
a gate structure extending in a first direction on the substrate insulating layer;
a plurality of channel layers spaced apart from each other in a second direction, the second direction perpendicular to an upper surface of the substrate insulating layer;
the plurality of channel layers on the substrate insulating layer, and surrounded by the gate structure;
a first source/drain region on a first side of the gate structure and connecting to the plurality of channel layers;
a second source/drain region on a second side of the gate structure, the second side opposite to the first side and connecting to the plurality of channel layers;
a first spacer layer between the first source/drain region and the substrate insulating layer;
a second spacer layer between the second source/drain region and the substrate insulating layer;
a backside contact plug penetrating the substrate insulating layer and the first spacer layer and connecting to the first source/drain region; and
a front side contact plug partially recessing the upper surface of the second source/drain region,
wherein the first source/drain region includes
a backside epitaxial layer contacting the backside contact plug, and
a concentration of a non-silicon element included in the backside epitaxial layer is greater than a concentration of a non-silicon element included in the second source/drain region.

20. The semiconductor device of claim 19, further comprising a backside power structure connecting to the backside contact plug below the substrate insulating layer.
